(19) United States
(12) Patent Application Publication
(10) Pub. No.: US 2017/0125171 A1
(43) Pub. Date: May 4, 2017

(54) ORGANIC-INORGANIC HYBRID SOLAR CELL

(71) Applicant: LG CHEM, LTD., Seoul (KR)

(72) Inventors: Hangken LEE, Daejeon (KR); Songrim JANG, Daejeon (KR); Jaechol LEE, Daejeon (KR); Jinseck KIM, Daejeon (KR); Doowhan CHOI, Daejeon (KR); Jiwon BANG, Daejeon (KR); Donggu LEE, Daejeon (KR)

(21) Appl. No.: 15/303,191

(22) PCT Filed: Apr. 21, 2015
(86) PCT No.: PCT/KR2015/003987

§ 371 Date: Oct. 10, 2016

(30) Foreign Application Priority Data
Apr. 23, 2014 (KR) 10-2014-0048916

(51) Int. Cl. H01G 9/20; H01L 51/42

(52) U.S. Cl. CPC H01G 9/2009; H01L 51/4213; H01G 9/2031; H01G 9/2036; H01G 9/204; H01L 51/0077

(57) ABSTRACT

The present specification relates to an organic-inorganic hybrid solar cell.

### TECHNICAL FIELD

This specification claims priority to and the benefit of Korean Patent Application No. 10-2014-0048916 filed in the Korean Intellectual Property Office on Apr. 23, 2014, the entire contents of which are incorporated herein by reference.

The present specification relates to an organic-inorganic hybrid solar cell.

### BACKGROUND ART

In order to solve the global environmental problems caused by the depletion of fossil fuels and the use thereof, studies have been actively conducted on alternative energy sources, which may be regenerated and are clean, such as solar energy, wind power, and water power. Among them, interests in solar cells which change electric energy directly from the sunlight have been greatly increased. Here, the solar cell means a cell which produces current-voltage by absorbing photoenergy from the sunlight to use photovoltaic effects of generating electrons and holes.

Currently, n-p diode-type silicon (Si) single crystal-based solar cells having photoenergy conversion efficiency of more than 20% may be manufactured and are actually used in the photovoltaic power generation, and there are also solar cells using a compound semiconductor, such as gallium arsenide (GaAS), which has better conversion efficiency than the n-p diode-type silicon (Si) single crystal-based solar cells. However, these inorganic semiconductor-based solar cells require materials which are purified to a very high purity for high efficiency and thus a lot of energy are consumed for the purification of original materials, and expensive process equipment is also needed in the process of producing single crystals using original materials or making films thinner, so that there is a limitation in lowering costs of manufacturing a solar cell, which has been an obstacle for the utilization of the solar cells on a large scale.

Accordingly, the costs of a material, which is essentially used for a solar cell, or a manufacturing process for a solar cell need to be greatly reduced in order to manufacture a solar cell at low costs, and studies have been actively conducted on a dye-sensitized solar cell and an organic solar cell, which may be manufactured using inexpensive materials and processes as an alternative to an inorganic semiconductor-based solar cell.

A dye-sensitized solar cell was representatively reported by a research team of Michael Gratzel, et al., at the Swiss National Higher Institute of Technology in Lausanne (Ecole Polytechnique Fédérale de Lausanne, EPFL) in 1991. Below, the operating principle of the dye-sensitized solar cell is based on when solar energy is absorbed into a photosensitive dye adsorbed on a semiconductor layer of an electrode to generate photoelectrons, the photoelectrons are conducted through the semiconductor layer, and thus are transferred to a conductive transparent substrate in which a transparent electrode is formed, and the dye, which has lost electrons and thus is oxidized, is reduced by an oxidation•reduction pair included in the electrolyte. Specifically, the electrons, which reach a counter electrode, which is an opposite electrode, through an external electric wire, again reduce the oxidation•reduction pair of the oxidized electrolyte to complete the operation process of the solar cell.

In contrast, the dye-sensitized solar cell includes various interfaces such as a semiconductor|dye interface, a semiconductor|electrolyte interface, a semiconductor|transparent electrode interface, and an electrolyte|counter electrode interface, as compared to the existing solar cells, and it is an implemental key to the dye-sensitized solar cell technology to understand and control the physical•chemical actions at each interface. Further, the energy conversion efficiency of the dye-sensitized solar cell is proportional to the amount of photoelectrons produced by the solar energy absorption, and in order to produce a large amount of photoelectrons, it is required to manufacture a photoelectrode including a structure which may increase the amount of dye molecules adsorbed. However, a liquid-type dye-sensitized solar cell has relatively high efficiency and thus is likely to be commercialized, but there are a stability problem according to the time by a volatile liquid electrolyte and a problem with lowering the costs caused by using expensive ruthenium (Ru)-based dye. In order to solve the problems, studies have been conducted on the use of a non-volatile electrolyte using an ionic solvent instead of the volatile liquid electrolyte, the use of a polymer gel-type electrolyte, the use of an inexpensive pure organic material dye, and the like, but there is a problem in that the efficiency is lower than a dye-sensitized solar cell using a volatile liquid electrolyte and a Ru-based dye.

Accordingly, there is a need for developing an organic-inorganic hybrid solar cell having a perovskite structure instead of a ruthenium metal complex in the related art.

### CITATION LIST

### Non-Patent Document

Advanced Materials, 23 (2011) 4636

Nano Letters, 11 (2011) 4789

J. Am. Chem. Soc., 131 (2009) 6050

### DETAILED DESCRIPTION OF THE INVENTION

### Technical Problem

An object of the present specification is to provide an organic-inorganic hybrid solar cell which is excellent in stability and energy conversion efficiency.

### Technical Solution

The present specification provides an organic-inorganic hybrid solar cell including: a first electrode;

a second electrode provided to face the first electrode;

a photoactive layer provided between the first electrode and the second electrode; and

a silicon material layer provided between the photoactive layer and the first electrode,

in which the photoactive layer includes a compound having a perovskite structure.

### Advantageous Effects

An organic-inorganic hybrid solar cell according to an exemplary embodiment of the present specification has excellent charge mobility and thus may implement an increase in high current density and/or an increase in energy conversion efficiency.

Further, an organic-inorganic hybrid solar cell according to an exemplary embodiment of the present specification may absorb a wide light spectrum and thus may decrease the loss of photoenergy and may implement an increase in high current density and/or an increase in energy conversion efficiency.

The organic-inorganic hybrid solar cell according to an exemplary embodiment of the present specification may be manufactured by a simple manufacturing process and thus is economically efficient in terms of time and/or cost.

The organic-inorganic hybrid solar cell according to an exemplary embodiment of the present specification may increase an interfacial area and/or easily control the moving path of the charge, which are/is required for transporting charges.

### BRIEF DESCRIPTION OF DRAWINGS

FIGS. 1 to 9 each illustrate an example of the organic-inorganic hybrid solar cell according to an exemplary embodiment of the present specification.

### EXPLANATION OF REFERENCE NUMERALS AND SYMBOLS

101: Substrate

102: First electrode

103: Silicon material layer

104: Photoactive layer

105: Second electrode

106: Electron transporting layer

107: Hole transporting layer

108: Intermediate layer

### BEST MODE

Hereinafter, the present specification will be described in detail.

When one part “includes” one constituent element throughout the present specification, unless otherwise specifically described, this does not mean that another constituent element is excluded, but means that another constituent element may be further included.

When one member is disposed “on” another member throughout the present specification, this includes not only a case where the one member is brought into contact with the another member, but also a case where still another member is present between the two members.

An exemplary embodiment of the present specification provides an organic-inorganic hybrid solar cell including: a first electrode; a second electrode provided to face the first electrode; a photoactive layer provided between the first electrode and the second electrode; and a silicon material layer provided between the photoactive layer and the first electrode, in which the photoactive layer includes a compound having a perovskite structure.

In the present specification, the compound having a perovskite structure may be a compound having a perovskite structure, in which inorganic materials and organic materials are intermingled and combined. Specifically, in an exemplary embodiment of the present specification, the compound having a perovskite structure is an organic-metal halogen compound having a perovskite structure.

In another exemplary embodiment, three constituent ions may satisfy the following Equation 1 in order to obtain the compound having a perovskite structure.

$$t = \frac{( {R}_{A} + {R}_{O} )}{\sqrt{2} ( {R}_{B} + {R}_{O} )} \qquad [ Equation 1 ]$$

In Equation 1,

R_{A}, R_{B}, and R_{O} mean a radius of each ion, and

t is a tolerance factor indicating the contact state of the ions, and the case where t is 1 means a compound having an ideal perovskite structure in which each ion is brought into contact with an adjacent ion.

In one exemplary embodiment, the compound having a perovskite structure is represented by the following Chemical Formula 1.

AMX₃ [Chemical Formula 1]

In Chemical Formula 1,

A is a monovalent organic ammonium ion or Cs⁺,

M is a divalent metal ion, and

X is a halogen ion.

In an exemplary embodiment of the present specification, the compound satisfying Chemical Formula 1 may have a perovskite structure, M may be disposed at the center of a unit cell in the perovskite structure, X may be disposed at the center of each surface of the unit cell and thus may form an octahedron structure around M, and A may be disposed at each corner of the unit cell.

In another exemplary embodiment, Chemical Formula 1 is represented by the following Chemical Formula 2 or 3.

(R1−NH₃⁺)MX₃ [Chemical Formula 2]

(R2−C₃H₄N₂⁺−R3)MX₃ [Chemical Formula 3]

In Chemical Formulae 2 and 3,

R1 and R2 are a substituted or unsubstituted alkyl group having 1 to 24 carbon atoms; a substituted or unsubstituted cycloalkyl group having 3 to 20 carbon atoms; or a substituted or unsubstituted aryl group having 6 to 20 carbon atoms,

R3 is hydrogen; or an alkyl group having 1 to 24 carbon atoms,

M is a divalent metal ion in which one or two or more is/are selected from the group consisting of Cu²⁺, Ni²⁺, Co²⁺, Fe²⁺, Mn²⁺, Cr²⁺, Pd²⁺, Cd²⁺, Ge²⁺, Sn²⁺, Pd²⁺, and Yb²⁺, and

X is a halogen ion in which one or two or more is/are selected from the group consisting of F⁻, Cl⁻, Br⁻, and I⁻.

In an exemplary embodiment of the present specification, the compound having a perovskite structure includes three X's, which are a halogen ion, and the three halogen ions may be the same as or different from each other.

In an exemplary embodiment of the present specification, M is Pd²⁺.

In another exemplary embodiment, R1 is an alkyl group having 1 to 24 carbon atoms.

In an exemplary embodiment of the present specification, R1 is a methyl group.

In another exemplary embodiment, the organic-metal halogen compound is one or two or more selected from the group consisting of CH₃NH₃PbIₓCl_{y}, CH₃NH₃PbIₓBr_{y}, CH₃NH₃PbClₓBr_{y}, and CH₃NH₃PbIₓF_{y}, x is a real number of 0 to 3, y is a real number of 0 to 3, and x+y=3.

In an exemplary embodiment of the present specification, the photoactive layer includes only a compound having a perovskite structure.

In an exemplary embodiment of the present specification, the photoactive layer includes one or two or more selected from the group consisting of compounds having a perovskite structure represented by Chemical Formula 1 and compounds having other perovskite structures.

When the photoactive layer includes two compounds having a perovskite structure, the content range of the compound having a perovskite structure represented by Chemical Formula 1 and the compound having another perovskite structure is 1:1,000 to 1,000:1. In another exemplary embodiment, the content range of the compound having a perovskite structure represented by Chemical Formula 1 and the compound having another perovskite structure is 1:100 to 100:1. In still another exemplary embodiment, the content range of the compound having a perovskite structure represented by Chemical Formula 1 and the compound having another perovskite structure is 1:10 to 10:1.

The compound having a perovskite structure has a higher extinction coefficient than general materials included in the photoactive layer and thus has an excellent light harvesting efficiency even in a film having a thin thickness. Accordingly, the organic-inorganic hybrid solar cell according to an exemplary embodiment of the present specification may expect excellent energy conversion efficiency.

In one exemplary embodiment, the photoactive layer including the compound having a perovskite structure has a thickness of 50 nm to 2,000 nm. In another exemplary embodiment, the photoactive layer including the compound having a perovskite structure has a thickness of 100 nm to 1,500 nm. In still another exemplary embodiment, the photoactive layer including the compound having a perovskite structure has a thickness of 300 nm to 1,000 nm.

In the present specification, the term “thickness” means a width between one surface to face a first electrode or a second electrode and one surface to face the surface.

The organic-inorganic hybrid solar cell according to an exemplary embodiment of the present specification includes a silicon material layer between a photoactive layer and a first electrode.

In the case of a cell including a compound having a perovskite structure in the related art, it is difficult to expect an improvement in current density due to the loss of current caused by low charge mobility. Further, the compound having a perovskite structure may not absorb a light spectrum of 800 nm or more and thus has a large loss of photoenergy. In order to prevent the loss of photoenergy, a method of increasing the thickness of the photoactive layer may be considered, but when the thickness of the photoactive layer is increased, the loss of current may occur due to a decrease in charge mobility of the photoactive layer.

Since the organic-inorganic hybrid solar cell according to an exemplary embodiment of the present specification may further include a silicon material layer having a relatively excellent charge mobility compared to the compound having a perovskite structure, thereby preventing the loss of current to improve the current density. Further, the silicon material layer may absorb a light spectrum of 800 nm or more to prevent the loss of photoenergy and thus may implement high energy conversion efficiency, and the silicon material layer may easily control energy through doping and thus may easily control an energy injection barrier according to an energy level of the photoactive layer. Therefore, it is possible to increase an interfacial area and/or easily control the moving path of the charge, which are/is required for transporting charges.

In addition, the silicon material may use a solution process to control the form of the junction surface with a photoactive layer including a compound having a perovskite structure, may enhance the current density through an improvement in current collection area and photoabsorption characteristics, and is economically efficient in terms of time and/or cost in manufacturing a solar cell.

In the present specification, the term “charge” means an electron or a hole.

In an exemplary embodiment of the present specification, the silicon material layer is provided in the form of a film; or in the form of a pattern.

The film form means having a smooth surface, the pattern form means having an unevenness, and it is possible to achieve a structure of a surface such as a form of a nanowire, a pyramid, and a dome.

The silicon included in the silicon material layer may be a p-type or an n-type, may be amorphous or crystalline, and may be a nanoparticle or wafer-type, and may be controlled and used without limiting the form, if necessary.

For example, a person with ordinary skill in the art may use a state in which impurities are not added to silicon, if necessary, and may use p-type or n-type doped silicon by adding impurities to silicon. P-type amorphous silicon is made by infiltrating boron, potassium, and the like, which are a trivalent element, and n-type amorphous silicon is made by adding phosphorus, arsenic, potassium, and the like, which are a pentavalent element.

In an exemplary embodiment of the present specification, the silicon material layer is in the form of a pattern.

In an exemplary embodiment of the present specification, the silicon material layer may control surface energy and/or charge recombination characteristics through surface modification by using a surface oxidation method using a self-assembled monolayer (SAM) and a parallel plate-type discharge, a method of oxidizing the surface through ozone produced using UV light in a vacuum state, a method of performing oxidization using oxygen radicals produced by plasma, and a method of forming a silicon oxide (SiO₂), and the like, in order to modify the surface.

In an exemplary embodiment of the present specification, the silicon material layer may achieve a nanostructure, such as the form of nanorod, cone, pyramid, and semi-sphere, by using a dry method such as lithography using oxygen, trifluoromethane, chlorine, hydrogen bromide plasma, and the like, and a wet method using hydrofluoric acid, and the like, in order to achieve the surface structure.

When a silicon material layer in the form of a pattern is included, it is possible to expect an increase in current density according to the increase in collection area of the charge as the junction area is improved through the achievement of the nanostructure. Further, due to the light trapping and/or antireflection effects, the light absorption rate is increased, and the current density may be increased.

In an exemplary embodiment of the present specification, the silicon material layer in the form of a film has a thickness of 300 micrometers to 600 micrometers. In another exemplary embodiment, the silicon material layer in the form of a film has a thickness of 400 micrometers to 550 micrometers.

In an exemplary embodiment of the present specification, the pattern of the silicon material layer in the form of a pattern has a thickness of 30 nm to 1,000 nm. In another exemplary embodiment, the pattern of the silicon material layer in the form of a pattern has a thickness of 50 nm to 800 nm.

The thickness of the pattern means a width between one surface including a pattern and one surface of a pattern to face the surface including a pattern. That is, the thickness of the pattern means a height of a pattern provided in the silicon material layer in the form of a film, and means an average value of two or more pattern heights when two or more patterns are included.

In an exemplary embodiment of the present specification, the silicon material layer and the photoactive layer are provided to be in contact with each other.

In another exemplary embodiment, an intermediate layer provided between the silicon material layer and the photoactive layer is further included.

In an exemplary embodiment of the present specification, the intermediate layer is an insulation layer; or an N/P junction layer.

In an exemplary embodiment of the present specification, an inorganic insulating material, an organic insulating material, or a mixture thereof is included as a material constituting the insulation layer.

Specifically, the inorganic insulating material may be selected from the group consisting of silicon oxide, silicon nitride, titanium oxide, aluminum oxide, magnesium oxide, zinc oxide, specifically, nanoparticles of oxides such as alumina (Al₂O₃), zirconia (ZrO), and silica (SiO₂), lithium fluoride (LiF), and the like. As the organic insulating material, a material such as polystyrene (PS), poly(methylmethacrylate), polyester, an ethylene-vinylacetate copolymer, acryl, epoxy, and polyurethane may also be used, a material such as a non-conjugated polyelectrolyte may be used, and the person with ordinary skill in the art may select the material, if necessary.

When the insulating layer is included, it is possible to improve the resistance contact between the silicon material layer and the photoactive layer, it is possible to improve the energy conversion efficiency by providing a space capable of effectively recombining excited electrons and holes, and it is possible to obtain a uniform thin film by controlling surface energy to improve wettability of a solution layer disposed on an upper portion.

In another exemplary embodiment, the intermediate layer is an N/P junction layer.

In an exemplary embodiment of the present specification, a constituent material forming the N/P junction layer includes one or two or more selected from the group consisting of metal oxides, metals, conducting polymers, dielectric materials, and carbon compounds.

In the present specification, the metal may be any one metal selected from the group consisting of titanium (Ti), zirconium (Zr), strontium (Sr), zinc (Zn), indium (In), lanthanum (La), vanadium (V), molybdenum (Mo), tungsten (W), tin (Sn), niobium (Nb), magnesium (Mg), calcium (Ca), barium (Ba), aluminum (Al), yttrium (Y), scandium (Sc), samarium (Sm), gallium (Ga), and strontium titanate (SrTi), and is not limited thereto.

In the present specification, the metal oxide is an oxide of the above-described metal, and specific examples thereof include a Mo oxide, a V oxide, a Ni oxide, a Ti oxide, a Zn oxide, and the like, and are not limited thereto. Specifically, the metal oxide may be one selected from the group consisting of MoO₃, V₂O₅, VOₓ, TiO₂, TiOₓ, and ZnO.

In the present specification, examples of the conductive polymer include poly(3,4-ethylenedioxythiophene) (PEDOT), polyacrylic acid (PAA), and the like, and are not limited thereto.

In the present specification, examples of the dielectric material include polyethyleneimine (PEI), ethoxylated polyethyleneimine (PEIE), poly[(9,9-bis(3′-(N,N-dimethylamino)propyl)-2,7-fluorene)-alt-2,7-(9,9-dioctylfluorene)] (PFN), and the like, and are not limited thereto.

In the present specification, examples of the carbon compound include graphene, carbon nanotube (CNT), and the like, but are not limited thereto.

In an exemplary embodiment of the present specification, specific examples of the N/P junction layer include ZnO/Al, Ag/PEDOT, ZnO/Al, Ag/PEI, PEIE, ZnO/a conjugated polyelectrolyte/with or without Al/PEDOT, ZnO/graphene, Al or Ag/a conjugated polyelectrolyte, and the like, and are not limited thereto.

Specifically, the intermediate layer may form a junction layer of ZnO/PEDOT:PSS, and may be doped with an n-type or p-type material to form a junction layer.

In the present specification, the N/P junction layer serves to allow carriers, which are produced at both the silicon material layer and the photoactive layer including a compound having a perovskite structure, to move and recombine with each other in the N/P junction layer and allow charges to move to the opposite electrode, and serves to decrease the interface resistance.

In the present specification, the p doping layer means a layer doped with p-dopants. The p-dopant means a material which allows a host material to have p-semiconductor characteristics. The p-semiconductor characteristics mean characteristics that holes are injected or transported at the highest unoccupied molecular orbit (HOMO) energy level, that is, characteristics of a material having a large hole conductivity.

In the present specification, the n doping layer means a layer doped with n-dopants. The n-dopant means a material which allows a host material to have n semiconductor characteristics. The n-semiconductor characteristics mean characteristics that electrons are injected or transported at the lowest unoccupied molecular orbit (LUMO) energy level, that is, characteristics of a material having a large electron conductivity.

In an exemplary embodiment of the present specification, the organic-inorganic hybrid solar cell may have a tandem structure. In this case, the organic-inorganic hybrid solar cell may include two or more photoactive layers.

In another exemplary embodiment, the silicon material layer is provided to be in contact with the first electrode.

In the present specification, when the silicon material layer is provided to be in contact with the first electrode, the silicon material layer may serve to support a solar cell as a substrate role in the solar cell. Therefore, the solar cell may act as a solar cell without provision of a separate substrate.

In one exemplary embodiment, when the silicon material layer is provided to be in contact with the first electrode, the first electrode and the second electrode are the same as or different from each other, and may be independently selected from the group consisting of a metal electrode, a conductive polymer, and a combination thereof.

In the present specification, the metal electrode may include one or two or more selected from the group consisting of silver (Ag), gold (Au), aluminum (Al), platinum (Pt), tungsten (W), copper (Cu), molybdenum (Mo), gold (Au), nickel (Ni), and palladium (Pd).

In the present specification, the conductive polymer may be selected from thiophene-based, paraphenylene vinylene-based, carbazole-based or triphenylamine-based polymers, but is not limited thereto as long as the conductive polymer is a conductive material.

Specifically, examples of the polymer include poly[3-hexylthiophene] (P3HT), poly[2-methoxy-5-(3′,7′-dimethyloctyloxyl)]-1,4-phenylene vinylene (MDMO-PPV), poly[2-methoxy-5-(2″-ethylhexyloxy)-p-phenylene vinylene] (MEH-PPV), poly(3-octyl thiophene) (P3OT), poly(3-decyl thiophene) (P3DT), poly(3-dodecyl thiophene) (P3DDT), poly(p-phenylene vinylene) (PPV), poly(9,9′-dioctylfluorene-co-N-(4-butylphenyl)diphenyl amine (TFB), poly[2,1,3-benzothiadiazole-4,7-diyl[4,4-bis(2-ethylhexyl-4H-cyclopenta [2,1-b:3,4-b′]dithiophene-2,6-diyl] (PCPDTBT), poly[(4,4′-bis(2-ethylhexyl)dithieno[3,2-b:2′,3′-d]silole)-2,6-diyl-alt-(2,1,3-benzothiadiazole)-4,7-diyl] (Si-PCPDTBT), poly((4,8-diethylhexyloxyl)benzo([1,2-b:4,5-b 40 ]dithiophene)-2,6-diyl)-alt-((5-octylthieno[3,4-c]pyrrole-4,6-dione)-1,3-diyl) (PBDTTPD), poly[2,7-(9-(2-ethylhexyl)-9-hexyl-fluorene)-alt-5,5-(4′,7,-di-2-thienyl-2′,1′,3′-benzothiadiazole)] (PFDTBT), poly[2,7-.9,9-(dioctyl-fluorene)-alt-5,5-(4′,7′-di-2-.thienyl-2′,1′,3′-benzothiadiazole)] (PFO-DBT), poly[(2,7-dioctylsilafluorene)-2,7-diyl-alt-(4,7-bis(2-thienyl)-2,1,3-benzothiadiazole)-5,5′-diyl] (PSiFDTBT), poly[(4,4′-bis(2-ethylhexyl)dithieno[3,2-b:2′,3′-d]silole)-2,6-diyl-alt-(2,1,3-benzothiadiazole)-4,7-diyl] (PSBTBT), poly [[9-(1-octylnonyl)-9H-carbazole-2,7-diyl]-2,5-thiophenediyl-2,1,3-benzothiadiazole-4,7-diyl-2,5-thiophenediyl] (PCDTBT), poly(9,9′-dioctylfluorene-co-bis(N,N′-(4,butylphenyl))bis(N,N′-phenyl-1,4-phenylene)diamine (PFB), poly(9,9′-dioctylfluorene-co-benzothiadiazole) (F8BT), poly(3,4-ethylenedioxythiophene) (PEDOT), poly(3,4-ethylenedioxythiophene):poly(styrenesulfonate) (PEDOT: PSS), poly(triarylamine) (PTAA), poly(4-butylphenyl-diphenyl-amine), a copolymer thereof, and the like, and are not limited thereto.

In one exemplary embodiment, the first electrode and the second electrode are the same as or different from each other, and each independently include those selected from the group consisting of silver (Ag), gold (Au), aluminum (Al), platinum (Pt), tungsten (W), copper (Cu), a conductive polymer, and a combination thereof.

In an exemplary embodiment of the present specification, a substrate is further included on a surface to face the surface of the first electrode on which the photoactive layer is provided.

In this case, the first electrode is selected from the group consisting of indium-tin oxide (ITO), fluorine-doped tin oxide (FTC)), indium zinc oxide (IZO), aluminum-zinc oxide ((AZO); ZnO:Al), aluminum-tin oxide ((ATO); SnO₂:Al), tin-based oxide, zinc oxide (ZnO), and a combination thereof, and

the second electrode is selected from the group consisting of a metal electrode, a conductive polymer, and a combination thereof.

The metal electrode and the conductive polymer are the same as those described above.

As the substrate in the present specification, an organic material such as a flexible plastic, glass, or a metal may be used. In this case, as the organic material, it is possible to use polyimide (PI), polycarbonate (PC), polyethersulfone (PES), polyether ether ketone (PEEK), polybutylene terephthalate (PBT), polyethylene terephthalate (PET), polyvinyl chloride (PVC), polyethylene (PE), an ethylene copolymer, polypropylene (PP), a propylene copolymer, poly(4-methyl-1-pentene) (TPX), polyarylate (PAR), polyacetal (POM), polyphenylene oxide (PPO), polysulfone (PSF), polyphenylene sulfide (PPS), polyvinylidene chloride (PVDC), polyvinyl acetate (PVAC), polyvinyl alcohol (PVAL), polyvinyl acetal, polystyrene (PS), an AS resin, an ABS resin, polymethylmethacrylate (PMMA), a fluorine resin, a phenol resin (PF), a melamine resin (MF), a urea resin (UF), unsaturated polyester (UP), an epoxy resin (EP), a diallyl phthalate resin (DAP), polyurethane (PUR), polyamide (PA), a silicone resin (SI) or mixtures and compounds thereof.

In an exemplary embodiment of the present specification, one or more layers selected from the group consisting of a hole injection layer, a hole transporting layer, an electron blocking layer, an electron transporting layer, and an electron injection layer are further included between the first electrode and the second electrode.

In one exemplary embodiment, an electron transporting layer is further included between the first electrode and the silicon material layer.

In another exemplary embodiment, a hole transporting layer is further included between the second electrode and the photoactive layer.

In an electron transporting layer is included between the first electrode and the silicon material layer, and a hole transporting layer is further included between the second electrode and the photoactive layer.

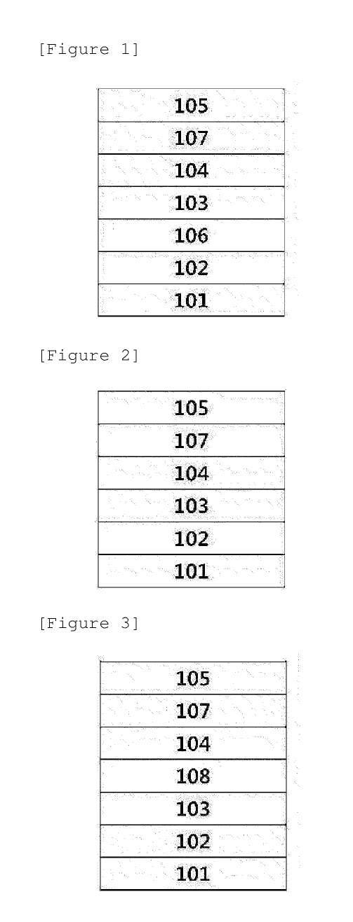

For example, the structure of the organic solar cell according to an exemplary embodiment of the present specification is exemplified in FIGS. 1 to 9, but is not limited thereto.

FIG. 1 is a view exemplifying an organic solar cell including a substrate 101, a first electrode 102 provided on the substrate 101, an electron transporting layer 106 provided on the first electrode 102, a silicon material layer 103 provided on the electron transporting layer 106, a photoactive layer 104 including a compound having a perovskite structure provided on the silicon material layer 103, a hole transporting layer 107 provided on the photoactive layer 104, and a second electrode 105 provided on the hole transporting layer 107.

FIG. 2 is a view exemplifying an organic solar cell including a substrate 101, a first electrode 102 provided on the substrate 101, a silicon material layer 103 provided on the first electrode 102, a photoactive layer 104 including a compound having a perovskite structure provided on the silicon material layer 103, a hole transporting layer 107 provided on the photoactive layer 104, and a second electrode 105 provided on the hole transporting layer 107.

FIG. 3 is a view exemplifying an organic solar cell including a substrate 101, a first electrode 102 provided on the substrate 101, a silicon material layer 103 provided on the first electrode 102, an intermediate layer 108 provided on the silicon material layer 103, a photoactive layer 104 including a compound having a perovskite structure provided on the intermediate layer 108, a hole transporting layer 107 provided on the photoactive layer 104, and a second electrode 105 provided on the hole transporting layer 107.

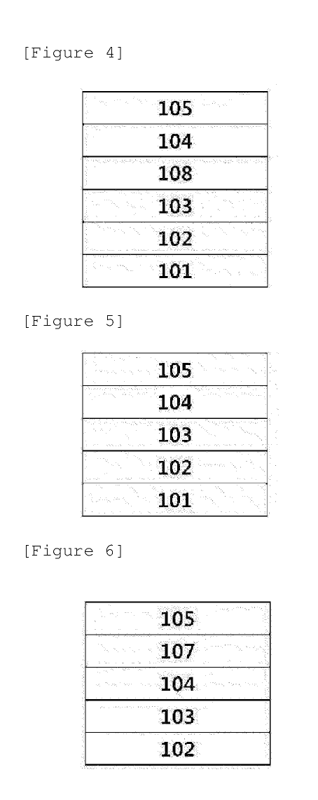

FIG. 4 is a view exemplifying an organic solar cell including a substrate 101, a first electrode 102 provided on the substrate 101, a silicon material layer 103 provided on the first electrode 102, an intermediate layer 108 provided on the silicon material layer 103, a photoactive layer 104 including a compound having a perovskite structure provided on the intermediate layer 108, and a second electrode 105 provided on the photoactive layer 104.

FIG. 5 is a view exemplifying an organic solar cell including a substrate 101, a first electrode 102 provided on the substrate 101, a silicon material layer 103 provided on the first electrode 102, a photoactive layer 104 including a compound having a perovskite structure provided on the silicon material layer 103, and a second electrode 105 provided on the photoactive layer 104.

In the case of FIGS. 1 to 5, the first electrode may be selected from the group consisting of indium-tin oxide (ITO), fluorine-doped tin oxide (FTC)), indium zinc oxide (IZO), aluminum-zinc oxide ((AZO); ZnO:Al), aluminum-tin oxide ((ATO); SnO₂:Al), tin-based oxide, zinc oxide (ZnO), and a combination thereof, and the second electrode may be selected from the group consisting of a metal electrode, a conductive polymer, and a combination thereof.

FIG. 6 illustrates a view of an organic solar cell including a first electrode 102, a silicon material layer 103 provided on the first electrode 102, a photoactive layer 104 including a compound having a perovskite structure provided on the silicon material layer 103, a hole transporting layer 107 provided on the photoactive layer 104, and a second electrode 105 provided on the hole transporting layer 107.

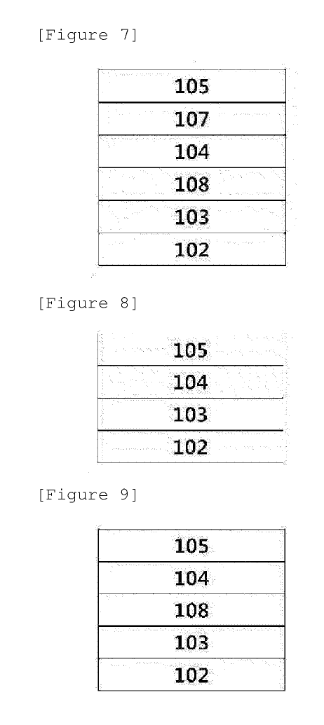

FIG. 7 is a view exemplifying an organic solar cell including a first electrode 102, a silicon material layer 103 provided on the first electrode 102, an intermediate layer 108 provided on the silicon material layer 103, a photoactive layer 104 including a compound having a perovskite structure provided on the intermediate layer 108, a hole transporting layer 107 provided on the photoactive layer 104, and a second electrode 105 provided on the hole transporting layer 107.

FIG. 8 is a view exemplifying an organic solar cell including a first electrode 102, a silicon material layer 103 provided on the first electrode 102, a photoactive layer 104 including a compound having a perovskite structure provided on the silicon material layer 103, and a second electrode 105 provided on the photoactive layer 104.

FIG. 9 is a view exemplifying an organic solar cell including a first electrode 102, a silicon material layer 103 provided on the first electrode 102, an intermediate layer 108 provided on the silicon material layer 103, a photoactive layer 104 including a compound having a perovskite structure provided on the intermediate layer 108, and a second electrode 105 provided on the photoactive layer 104.

In the case of FIGS. 6 to 9, the first electrode and the second electrode are the same as or different from each other, and may be independently selected from the group consisting of a metal electrode, a conductive polymer, and a combination thereof.

When one member is disposed “on” another member in the present specification, this includes not only a case where the one member is brought into contact with the another member, but also a case where still another member is present between the two members.

The hole transporting layer and/or electron transporting layer material(s) may be a material which enhances the probability that charges produced by efficiently transferring electrons and holes to a photoactive layer are transported to electrodes, but are/is not particularly limited.

In an exemplary embodiment of the present specification, the electron transporting layer may include a metal oxide. As the metal oxide, it is possible to specifically use one or two or more selected from Ti oxide, Zn oxide, In oxide, Sn oxide, W oxide, Nb oxide, Mo oxide, Mg oxide, Zr oxide, Sr oxide, Yr oxide, La oxide, V oxide, Al oxide, Y oxide, Sc oxide, Sm oxide, Ga oxide, In oxide, SrTi oxide, and a composite thereof, but the metal oxide is not limited thereto.

In one exemplary embodiment, as the electron transporting layer, one or two or more is/are selected from the group consisting of ZnO, TiO₂, SnO₂, WO₃, and TiSrO₃.

According to an exemplary embodiment of the present specification, the electron transporting layer may be a cathode buffer layer.

In an exemplary embodiment of the present specification, the electron transporting layer may improve characteristics of charges using doping, and may modify the surface using a fluorene derivative, and the like. For example, the surface may be modified using a method of doping ZnO with a metal ion such as Cs and Al, as described in J. Mater. Chem. A, 2013 1, 11802. Further, it is possible to use a method of doping ZnO with a fullerene compound (C₆₀), as described in Adv. Mater. 2013, 25, 4766 or Appl. Phys. Lett. 93, 233304.

In an exemplary embodiment of the present specification, the hole transporting layer may include a conductive polymer. Specific examples of the conductive polymer are the same as those of the above-described electrode material.

In one exemplary embodiment, the hole transporting layer may act as a second electrode.

According to an exemplary embodiment of the present specification, the hole transporting layer may be an anode buffer layer.

In an exemplary embodiment of the present specification, the hole transporting layer may further contain one or two or more additives selected from n-dopants and p-dopants.

In an exemplary embodiment of the present specification, the hole transporting layer may further contain one or two or more additives selected from tertiary butyl pyridine (TBP) and lithium bis(trifluoro methanesulfonyl)imide (LiTFSI).

In the present specification, the p-dopant means a material which allows a host material to have p semiconductor characteristics. The p-semiconductor characteristics mean characteristics that electrons are injected or transported at the highest unoccupied molecular orbit (HOMO) energy level, in other words, characteristics of a material having a large hole conductivity.

In the present specification, the n-dopant means a material which allows a host material to have n-semiconductor characteristics. The n-semiconductor characteristics mean characteristics that electrons are injected or transported at the lowest unoccupied molecular orbit (LUMO) energy level, in other words, characteristics of a material having a large electron conductivity.

In an exemplary embodiment of the present specification, the p-dopant may be an organic material, an inorganic material, or an organic-inorganic composite.

In the present specification, examples of the inorganic material include tungsten oxide (WO₃), molybdenum oxide (MoO₃), and rhenium oxide (ReO₂), and the like, and are not limited thereto.

In the present specification, the organic material may be selected as one or two or more materials selected from the group consisting of tetrafluoro-tetracyanoquinodimethane (F4-TCNQ) and hexafluoro-tetracyanoquinodimethane, but is not limited thereto.

The hole transporting layer may increase the open-circuit voltage by containing the additive. The additive may be added in an amount of 0.05 mg to 50 mg per 1 g of the polymer.

An exemplary embodiment of the present specification provides a method for manufacturing an organic-inorganic solar cell, the method including: preparing a substrate; forming a first electrode on the substrate; forming a silicon material layer on the first electrode; forming a photoactive layer including a compound having a perovskite structure on the silicon material layer; and forming a second electrode on the photoactive layer.

In one exemplary embodiment, the method further includes forming an electron transporting layer prior to the forming of the silicon material layer after the forming of the first electrode.

In another exemplary embodiment, the method further includes forming an intermediate layer prior to the forming of the photoactive layer after the forming of the silicon material layer.

In still another exemplary embodiment, the method further includes forming a hole transporting layer prior to the forming of the second electrode after the forming of the photoactive layer.

Further, an exemplary embodiment of the present specification provides a method for manufacturing an organic-inorganic solar cell, the method including: forming a first electrode; forming a silicon material layer on the first electrode; forming a photoactive layer including a compound having a perovskite structure on the silicon material layer; and forming a second electrode on the photoactive layer.

As described above, when the silicon material layer is provided to be in contact with the first electrode after the forming of the first electrode, the silicon material layer may act as a substrate, and a step of preparing a separate substrate may be omitted. In this case, the method may further include the forming of the intermediate layer and/or the forming of the hole transporting layer.

The organic-inorganic hybrid solar cell according to an exemplary embodiment of the present specification may be manufactured by materials and methods known in the art.

In an exemplary embodiment of the present specification, each step may be formed using a spin coating method, a deposition method, or a printing method.

The printing method may include inkjet printing, gravure printing, spray coating, doctor blading, bar coating, gravure coating, brush painting, slot-die coating, and the like. However, the printing method is not limited thereto.

The deposition method does not limit physical, chemical deposition, and the like.

### Mode for Invention

Hereinafter, the present specification will be described in detail with reference to the Examples for specifically describing the present specification. However, the Examples according to the present specification may be modified in various forms, and it is not interpreted that the scope of the present specification is limited to the Examples described below in detail. The Examples of the present specification are provided for more completely describing the present specification to the person with ordinary skill in the art.

### EXAMPLE 1

An organic-inorganic hybrid solar cell with a structure of Al/Si/Si NW/Perovskite/Spiro-OmeTAD/PH500/Ag Grid was manufactured.

Specifically, an n-type silicon (100) wafer on Al was immersed in a hydrofluoric acid solution to which silver nitride was added, and a silicon nanowire (SiNW) was prepared using a chemical etching. After a solution of lead iodide (PbI₂) dissolved in dimethyl formamide (DMF) was spin-coated, and then dried for 5 minutes, the silicon nanowire was immersed in methylammonium iodide (CH₃NH₃I) dissolved in 2-propanol for several ten seconds, and then dried.

2,2′,7,7′-tetrakis-(N,N-di-4-methoxyphenylamino)-9,9′-spirobifluorene (Spiro-OMeTAD), 4-tert-butylpyridine, and lithium bis(trifluoromethane)sulfonimide (Li-TFSI) were dissolved in chlorobenzene, and then the resulting solution was spin-coated. After coating with PEPOT:PSS (PH500), a silver grid electrode was deposited under a vacuum of 1×10⁻⁷ torr.

### COMPARATIVE EXAMPLE 1

An organic-inorganic hybrid solar cell with a structure of ITO/ZnO/Perovskite/Spiro-OmeTAD/Ag was manufactured instead of the structure of the organic-inorganic hybrid solar cell manufactured in Example 1.

Specifically, a glass substrate coated with ITO was ultrasonically washed with each of acetone and ethanol for 30 minutes, and was subjected to surface treatment using UV-ozone treatment (UVO) for 15 minutes.

After a solution of lead iodide (PbI₂) dissolved in dimethyl formamide (DMF) was spin-coated, and then dried for 5 minutes, the glass substrate was immersed in methylammonium iodide (CH₃NH₃I) dissolved in 2-propanol for several ten seconds, and then dried.

After 2,2′,7,7′-tetrakis-(N,N-di-4-methoxyphenylamino)-9,9′-spirobifluorene (Spiro-OMeTAD), 4-tert-butylpyridine, and lithium bis(trifluoromethane)sulfonimide (Li-TFSI) were dissolved in chlorobenzene, the resulting solution was spin-coated, and then a silver electrode was deposited under a vacuum of 1×10⁻⁷ torr.

### COMPARATIVE EXAMPLE 2

An organic-inorganic hybrid solar cell was manufactured in the same manner as in Example 1, except that the process of preparing the silicon nanowire (SiNW) in Example 1 was not performed.

### COMPARATIVE EXAMPLE 3

An organic-inorganic hybrid solar cell was manufactured in the same manner as in Example 1, except that the process of preparing the silicon nanowire (SiNW) in Example 1 was not performed and the perovskite layer was not coated.

The photoelectric conversion characteristics of the organic-inorganic hybrid solar cells manufactured in Example 1 and Comparative Examples 1 to 3 were measured under the condition of 100 mW/cm² (AM 1.5), and the results are shown in the following Table 1.

TABLE 1

| | V_{oc} (V) | J_{sc} (mA/cm²) | FF | PCE (%) |
|---|---|---|---|---|
| Example 1 | 1.011 | 20.3 | 0.701 | 14.3 |
| Comparative Example 1 | 0.99 | 17.8 | 0.631 | 11.12 |
| Comparative Example 2 | 1.011 | 18.8 | 0.677 | 12.87 |
| Comparative Example 3 | 0.532 | 24.4 | 0.432 | 5.61 |

V_{OC}, J_{SC}, FF, and PCE mean an open-circuit voltage, a short-circuit current, a fill factor, and energy conversion efficiency, respectively. The open-circuit voltage and the short-circuit current are an X axis and an Y axis intercept, respectively, in the fourth quadrant of the voltage-current density curve, and as the two values are increased, the efficiency of the solar cell is preferably increased. In addition, the fill factor is a value obtained by dividing the area of a rectangle, which may be drawn within the curve, by the product of the short-circuit current and the open circuit voltage. The energy conversion efficiency may be obtained when these three values are divided by the intensity of the irradiated light, and the higher value is preferred.

From the results of Example 1 and Comparative Examples 2 and 3, it can be confirmed that as in the organic-inorganic hybrid solar cell according to an exemplary embodiment of the present specification, the case where the organic-inorganic hybrid solar cell includes both a silicon material layer and a photoactive layer including a compound having a perovskite structure is better than the case where the organic-inorganic hybrid solar cell includes only a photoactive layer including a compound having a perovskite structure or the case where the organic-inorganic hybrid solar cell does not include either of the two layers, in terms of charge mobility, and accordingly, an increase in high current density and/or an increase in energy conversion efficiency are/is obtained.

Further, when the results of Example 1 and Comparative Example 1 are compared with each other, it can be confirmed that an increase in high current density and/or an increase in energy conversion efficiency are/is obtained compared to the case of including a buffer layer including a metal oxide instead of the silicon material layer.

The results as described above are because the compound having a perovskite structure has a higher extinction coefficient than that of a general material included in the photoactive layer and thus has an excellent light harvesting effect even in a film with a thin thickness, and accordingly, an excellent energy conversion efficiency may be expected, and the current density may be improved by further including a silicon material layer having a relatively excellent charge mobility compared to the compound having a perovskite structure to prevent the loss of current.

1. An organic-inorganic hybrid solar cell comprising:
a first electrode;
a second electrode provided to face the first electrode;
a photoactive layer provided between the first electrode and the second electrode; and
a silicon material layer provided between the photoactive layer and the first electrode,
wherein the photoactive layer comprises a compound having a perovskite structure.

2. The organic-inorganic hybrid solar cell of claim 1,
wherein the compound having a perovskite structure is an organic-metal halogen compound having a perovskite structure.

3. The organic-inorganic hybrid solar cell of claim 1,
wherein the compound having a perovskite structure is represented by the following Chemical Formula 1:
AMX₃ [Chemical Formula 1]
in Chemical Formula 1,
A is a monovalent organic ammonium ion or Cs⁺,
M is a divalent metal ion, and
X is a halogen ion.

4. The organic-inorganic hybrid solar cell of claim 3,
wherein the compound having a perovskite structure represented by Chemical Formula 1 is represented by the following Chemical Formula 2 or the following Chemical Formula 3:
(R1−NH₃⁺)MX₃ [Chemical Formula 2]
(R2−C₃H₄N₂⁺−R3)MX₃ [Chemical Formula 3]
in Chemical Formula 2 and 3,
R1 and R2 are a substituted or unsubstituted alkyl group having 1 to 24 carbon atoms; a substituted or unsubstituted cycloalkyl group having 3 to 20 carbon atoms; or a substituted or unsubstituted aryl group having 6 to 20 carbon atoms,
R3 is hydrogen; or an alkyl group having 1 to 24 carbon atoms,
M is a divalent metal ion in which one or two or more is/are selected from the group consisting of Cu²⁺, Ni²⁺, Co²⁺, Fe²⁺, Mn²⁺, Cr²⁺, Pd²⁺, Cd²⁺, Ge²⁺, Sn²⁺, Pd²⁺, and Yb²⁺, and
X is a halogen ion in which one or two or more are selected from the group consisting of F, Cl, Br, and I.

5. The organic-inorganic hybrid solar cell of claim 2,
wherein the organic-metal halogen compound is one or two or more selected from the group consisting of CH₃NH₃PbIₓCl_{y}, CH₃NH₃PbIₓBr_{y}, CH₃NH₃PbClₓBr_{y}, and CH₃NH₃PbIₓF_{y},
x is a real number of 0 to 3,
y is a real number of 0 to 3, and
x+y=3.

6. The organic-inorganic hybrid solar cell of claim 1,
wherein the photoactive layer has a thickness of 50 nm to 2,000 nm.

7. The organic-inorganic hybrid solar cell of claim 1,
wherein the silicon material layer is provided in a form of a film; or in a form of a pattern.

8. The organic-inorganic hybrid solar cell of claim 1,
wherein the silicon material layer and the photoactive layer are provided to be in contact with each other.

9. The organic-inorganic hybrid solar cell of claim 1,
wherein the silicon material layer is provided to be in contact with the first electrode.

10. The organic-inorganic hybrid solar cell of claim 9,
wherein the first electrode and the second electrode are the same as or different from each other, and independently comprise those selected from the group consisting of a metal electrode, a conductive polymer, and a combination thereof.

11. The organic-inorganic hybrid solar cell of claim 1, further comprising:
a substrate on a surface to face the surface of the first electrode on which the photoactive layer is provided.

12. The organic-inorganic hybrid solar cell of claim 11,
wherein the first electrode is selected from the group consisting of indium-tin oxide (ITO), fluorine-doped tin oxide (FTC)), indium zinc oxide (IZO), aluminum-zinc oxide ((AZO); ZnO:Al), aluminum-tin oxide ((ATO); SnO₂:Al), tin-based oxide, zinc oxide (ZnO), and a combination thereof, and
the second electrode is selected from the group consisting of a metal electrode, a conductive polymer, and a combination thereof.

13. The organic-inorganic hybrid solar cell of claim 1, further comprising:
an intermediate layer between the silicon material layer and the photoactive layer.

14. The organic-inorganic hybrid solar cell of claim 13,
wherein the intermediate layer is an insulation layer; or a N/P junction layer.

15. The organic-inorganic hybrid solar cell of claim 1,
wherein the organic-inorganic hybrid solar cell is a tandem type.

16. The organic-inorganic hybrid solar cell of claim 1, further comprising:
one or more layers selected from the group consisting of a hole injection layer, a hole transporting layer, an electron blocking layer, an electron transporting layer, and an electron injection layer between the first electrode and the second electrode.
